(19) United States
(12) Patent Application Publication
(10) Pub. No.: US 2009/0168545 A1
(43) Pub. Date: Jul. 2, 2009

(54) Semiconductor Device and Method of Fabricating the Same

(76) Inventors: Sung Kun Park, Cheongju-si (KR); Kun Hyuk Lee, Dobong-gu (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/328,912

(22) Filed: Dec. 5, 2008

(30) Foreign Application Priority Data
Dec. 27, 2007 (KR) 10-2007-0139215

(51) Int. Cl. G11C 16/18; H01L 31/167; H01L 31/18

(52) U.S. Cl. 365/185.32; 257/82; 438/25; 257/E31.108; 257/E31.001

(57) ABSTRACT

Disclosed are a semiconductor device and a method of fabricating the same. The semiconductor device can include a first wafer including a light emitting diode (LED), a second wafer including a flash cell formed corresponding to the LED, and a conductive via that electrically connects the first wafer to the second wafer.

### CROSS-REFERENCE TO RELATED APPLICATION

The present application claims the benefit under 35 U.S.C. §119 of Korean Patent Application No. 10-2007-0139215, filed Dec. 27, 2007, which is hereby incorporated by reference in its entirety.

### BACKGROUND

Data is erased from a flash cell through various schemes. However, as data is programmed into or erased from the flash cell, the reliability for the flash cell is degraded.

### BRIEF SUMMARY

Embodiments of the present invention provide a semiconductor device and a method of fabricating the same, capable of improving retention and endurance of a flash cell.

According to an embodiment, a semiconductor device can include a first wafer including a light emitting diode (LED), a second wafer including a flash cell formed corresponding to the LED, and a conductive via which electrically connects the first wafer to the second wafer.

According to an embodiment, a method of fabricating a semiconductor device can include providing a first wafer including a light emitting diode (LED), and providing a second wafer including a flash cell, and forming a conductive via electrically connecting the first wafer to the second wafer, and bonding the first wafer to the second wafer.

In the semiconductor devices and the methods of fabricating the same according to embodiments, the retention and the endurance of the flash cell can be improved.

### BRIEF DESCRIPTION OF THE DRAWINGS

FIGS. 1 and 2 are views showing problems when data are recorded onto or erased from a flash cell; and

FIG. 3 is a view showing a semiconductor device according to an embodiment of the present invention.

### DETAILED DESCRIPTION

Embodiments of the present invention relate to a flash memory semiconductor device and method for manufacturing the same.

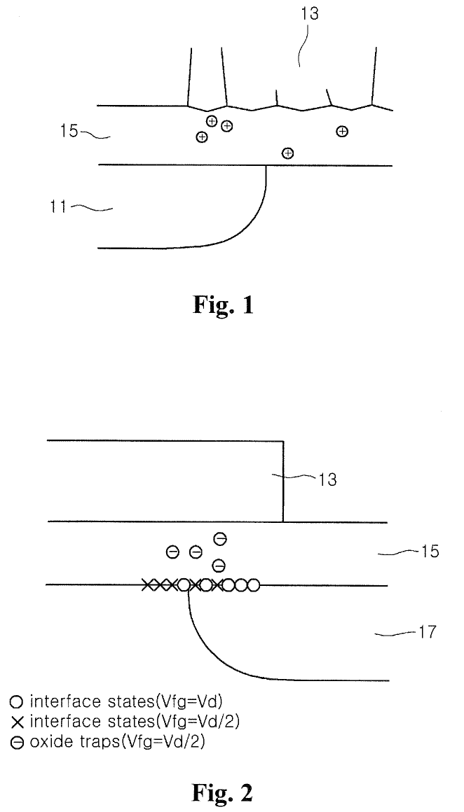

As shown in FIGS. 1 and 2, when data is recorded onto or erased from a tunnel oxide 15 of a flash cell, a trap may occur in the tunnel oxide 15. FIG. 1 is a view showing a trap when data is recorded by a source 11 and a floating gate 13, and FIG. 2 is a view showing a trap when data is erased by a drain 17 and the floating gate 13.

The trap of the tunnel oxide 15 degrades retention and endurance of the flash cell, which are reliability characteristics of the flash cell.

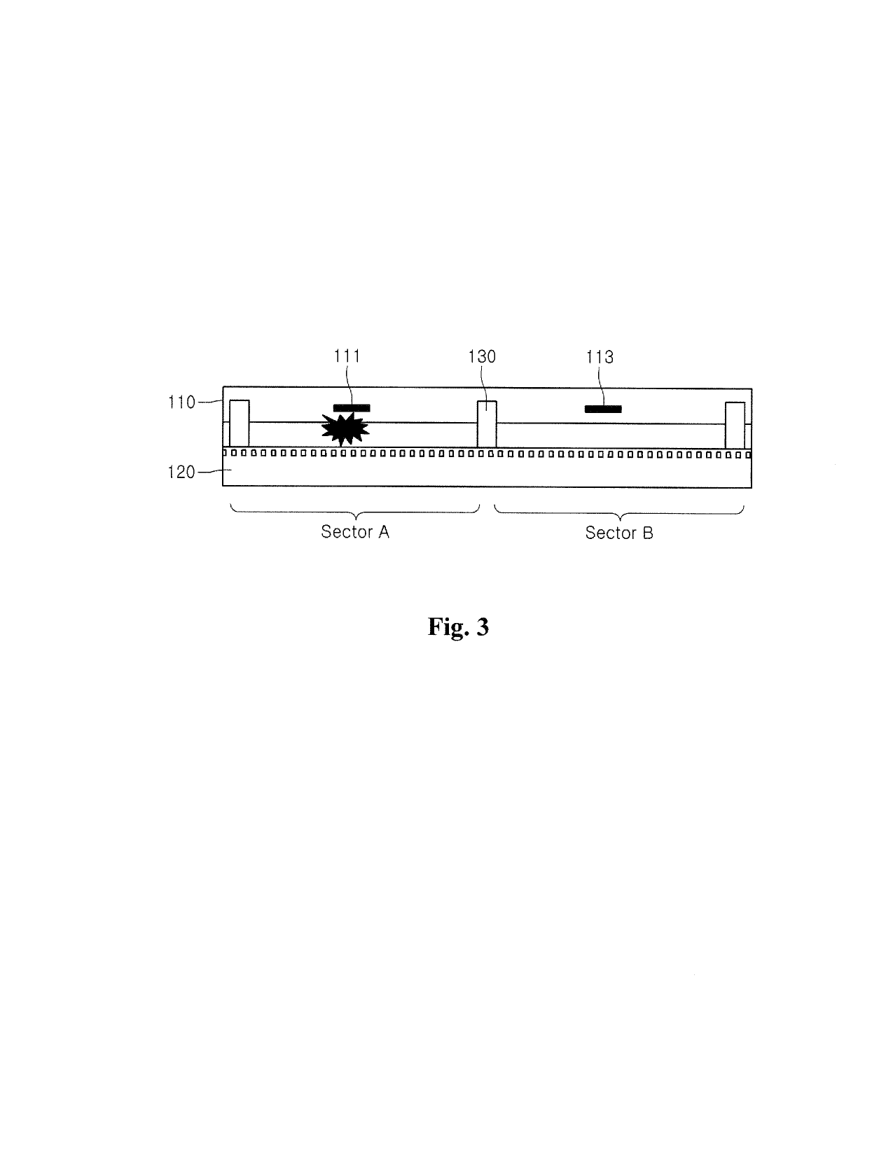

FIG. 3 is a view showing a semiconductor device according to an embodiment.

Referring to FIG. 3, the semiconductor device according to an embodiment includes a first wafer 110, a second wafer 120, and a conductive via 130. The first wafer 110 can be bonded with the second wafer 120 in a wafer level.

The first wafer 110 can be provided thereon with light emitting diodes (LEDs) 111 and 113. The second wafer 120 can be provided with flash cells formed corresponding to the LEDs 111 and 113.

The conductive via 130 electrically connects the first wafer 110 with the second wafer 120. For example, the conductive via 130 can be formed on the first and second wafers 110 and 120 by performing through silicon via (TSV) process.

The conductive via 130 formed through the TSV process can directly connect circuits provided on different wafers (i.e., the first and second wafers 110 and 120) to each other by using a via hole without wire bonding. According to an embodiment, a wafer-level flash device can be effectively realized by using the conductive via 130.

The LEDs 111 and 113 can be realized to emit light having an ultraviolet-ray wavelength band. Accordingly, data of a flash cell formed on the second wafer 120 can be erased by the light emitted from the LEDs 111 and 113. The LEDs 111 and 113 can emit light in a surface direction of the first wafer 110. Accordingly, the light emitted from the LEDs 111 and 113 can be transmitted to a wide area of the second wafer 120.

The wafer 110 can include a plurality of LEDs 111 and 113. Although only two LEDs 111 and 113 are shown in accompanying drawings, many more LEDs may be formed on the first wafer 110.

The second wafer 120 can include a plurality of flash cells, and the plural flash cells may be divided into a plurality of sectors. Although only two sectors A and B are shown in accompanying drawings, many more sectors may be formed on the second wafer 120.

According to an embodiment, data of each sector can be selectively erased by light emitted from each LED of each sector. For example, data of a flash cell positioned at the sector A can be erased by the light emitted from the LED 111 corresponding to the sector A. Since the LED 113 corresponding to the sector B does not emit light, data of a flash cell positioned at the sector B are not erased.

For example, electrons injected into a floating gate of a flash cell corresponding to the sector A are excited by ultraviolet rays from the LED 111 and emitted to an outside. Through the above process, data of the flash cell positioned at the sector A can be erased.

Data of a flash cell positioned at the sector B can be erased through light emission of the LED 113 corresponding to the sector B. In this case, since the LED 111 corresponding to the sector A does not emit light, data of the flash cell positioned at the sector A are not erased.

In addition, the LCDs 111 and 113 positioned on the sectors A and B may simultaneously emit light, so that data can be simultaneously erased from the flash cells positioned at the sectors A and B.

According to an embodiment, since data are erased by using a ultra-violet ray, traps do not occur even if data are repeatedly erased. Accordingly, the reliability of a flash cell can be maintained.

In addition, since a charge pump or an anti-excessive erasure circuit, which prevents data from being excessively erased in an existing device, is not required, the size of the semiconductor device can be further reduced.

The semiconductor device according to certain embodiments can be manufactured through the following processes.

A first wafer 110 can be provided with LEDs 111 and 113, and a second wafer 120 can be provided with a flash cell. The LEDs 111 and 113 are disposed to emit light in a surface direction of the first wafer 110. The first wafer 110 can be fabricated using methods suitable for forming LEDs. The second wafer 120 can be fabricated using methods suitable for forming flash cells.

Then, the conductive via 130 can be formed to electrically connect the first wafer 110 with the second wafer 120, and the first and second wafers 110 and 120 can be bonded to each other. For example, the conductive via 130 can be formed through a TSV process.

Thereafter, the first and second wafers 110 and 120 are cut, thereby forming a wafer-level device.

As described above, the wafer-level semiconductor device is designed to selectively erase data from each sector through light emission of the LED corresponding to each sector.

For example, data may be erased from a flash cell on the sector A through light emission of the LED 111 corresponding to the sector A. In this case, since the LED 113 corresponding to the sector B does not emit light, data of a flash cell positioned on the sector B may not be erased.

In addition, data may be erased from a flash cell positioned on the sector B through light emission of the LED 113 corresponding to the sector B. In this case, since the LED 111 corresponding to the sector A does not emit light, data of a flash cell positioned on the sector A may not be erased.

In addition, the LEDs 111 and 113 corresponding to the sectors A and B may simultaneously emit light, so that data can be simultaneously erased from flash cells positioned on the sectors A and B.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
a first wafer comprising a light emitting diode (LED);
a second wafer comprising a flash cell disposed corresponding to the LED; and
a conductive via electrically connecting the first wafer to the second wafer.

2. The semiconductor device of claim 1, wherein the conductive via is arranged on the first and second wafers through a through-silicon via (TSV) process.

3. The semiconductor device of claim 1, wherein the LED emits light of an ultraviolet-ray wavelength band, wherein data are erased from the flash cell by the light emitted from the LED.

4. The semiconductor device of claim 1, wherein the first wafer is bonded to the second wafer in a wafer level.

5. The semiconductor device of claim 1, wherein the first wafer comprises a plurality of LEDs,
wherein the second wafer comprises a plurality of flash cells, and
wherein the flash cells are divided into a plurality of sectors, wherein each LED of the plurality of LEDs is disposed corresponding to one of sectors of the plurality of sectors such that data of each sector are erased through light emission of the LED disposed corresponding to that sector.

6. The semiconductor device of claim 1, wherein the LED is disposed to emit light in a surface direction of the first wafer.

7. A method of fabricating a semiconductor device, the method comprising:
providing a first wafer comprising a light emitting diode (LED);
providing a second wafer comprising a flash cell;
forming a conductive via for electrically connecting the first wafer to the second wafer; and
bonding the first wafer to the second wafer.

8. The method of claim 7, wherein forming the conductive via comprises performing a through-silicon via (TSV) process.

9. The method of claim 7, further comprising cutting the bonded first and second wafers to form a wafer-level device.

10. The method of claim 7, wherein the LED is disposed to emit light in a surface direction of the first wafer.

11. The method of claim 7, wherein the first wafer comprises a plurality of LEDs,
wherein the second wafer comprises a plurality of flash cells, and
wherein the flash cells are divided into a plurality of sectors, wherein each LED of the plurality of LEDs is disposed corresponding to one of the sectors of the plurality of sectors such that data of each sector are erased through light emission of the LED disposed corresponding to that sector.
